(19) United States
(12) Patent Application Publication
(10) Pub. No.: US 2025/0031551 A1
(43) Pub. Date: Jan. 23, 2025

(54) DISPLAY DEVICE MANUFACTURING APPARATUS AND DISPLAY DEVICE MANUFACTURING METHOD

(71) Applicant: Samsung Display Co., LTD., Yongin-si (KR)

(72) Inventors: WONBEOM LEE, Yongin-si (KR); HYUK-HWAN KIM, Yongin-si (KR); JUNWOO YOU, Yongin-si (KR); SUK WON JUNG, Yongin-si (KR)

(21) Appl. No.: 18/676,722

(22) Filed: May 29, 2024

(30) Foreign Application Priority Data
Jul. 17, 2023 (KR) 10-2023-0092338

(51) Int. Cl. H10K 59/80; H10K 59/65

(52) U.S. Cl. CPC H10K 59/872; H10K 59/65

(57) ABSTRACT

A display device manufacturing apparatus includes a stage, on which a display panel including a front surface, which is a light-emitting surface, and a rear surface opposed to the front surface is provided in a way such that the rear surface is exposed, and a jig provided on the rear surface of the display panel on the stage, where a jig opening corresponding to the display panel is defined in the jig. The jig includes a jig body in which the jig opening is defined by an inner side surface thereof, where the jig body has a size smaller than a size of the display panel, a support part coupled to the jig body, disposed above the jig opening, and crossing the jig opening, and a block coupled to the support part and disposed inside the jig opening.

This application claims priority to Korean Patent Application No. 10-2023-0092338, filed on Jul. 17, 2023, and all the benefits accruing therefrom under 35 U.S.C. § 119, the content of which in its entirety is herein incorporated by reference.

### BACKGROUND

### 1. Field

The disclosure herein relates to a display device manufacturing apparatus and a display device manufacturing method, and more particularly, to a display device manufacturing apparatus including a jig and a display device manufacturing method.

### 2. Description of the Related Art

Various display devices used for multimedia devices such as a television, a mobile phone, a tablet computer, and a game console are being developed. A display device may include various functional layers in order to provide a color image with excellent quality to a user.

Recently, studies are being conducted on a thin display device to achieve various types of display devices such as a display device including a curved surface, a rollable display device, or a foldable display device. Also, a display device having a thin thickness may be achieved by reducing the number of functional layers and by including a functional layer including various functions.

### SUMMARY

To implement a display device having a thin thickness, it is desired to secure an impact resistance since the display device having a thin thickness may be prone to be damaged due to an impact occurring during the manufacturing of the display device. Therefore, studies are being conducted on a structure of a display device having a high impact resistance as well as a thin thickness.

The disclosure provides a display device manufacturing apparatus, with which a cover panel with a hole defined therein may be manufactured by using a jig including a support part and a block, and a display device manufacturing method using the display device manufacturing apparatus.

An embodiment of the invention provides a display device manufacturing apparatus including: a stage, on which a display panel including a front surface, which is a light-emitting surface, and a rear surface opposed to the front surface is provided in a way such that the rear surface is exposed; and a jig which is provided on the rear surface of the display panel on the stage, where a jig opening corresponding to the display panel is defined in the jig, where the jig includes a jig body in which the jig opening is defined by an inner side surface thereof, where the jig body has a size smaller than a size of the display panel, a support part coupled to the jig body, disposed above the jig opening, and crossing the jig opening, and a block coupled to the support part and disposed inside the jig opening.

In an embodiment, the support part may cross the jig opening along a direction in which a width of the jig opening is relatively short.

In an embodiment, the support part may include a support body overlapping the jig opening and crossing the jig opening, and terminal portions extending from opposing ends of the support body, and coupled to the jig body.

In an embodiment, a coupling groove may be defined in an upper surface of the jig body, and the terminal portions of the support part may be detachably coupled to the coupling groove.

In an embodiment, the coupling groove may be defined in plurality, and the terminal portions of the support part may be detachably coupled to two corresponding coupling grooves among a plurality of coupling grooves.

In an embodiment, the display device manufacturing apparatus may further include a coating layer disposed on the inner side surface of the jig body and on an outer side surface of the block.

In an embodiment, the support part may be provided in plurality, the block is provided in plurality, and at least one of a plurality of blocks is coupled to each of a plurality of support parts.

In an embodiment, the support part may cross the jig opening along a direction in which a width of the jig opening is great.

In an embodiment, a lower surface of the jig body and a lower surface of the block may be disposed on the same plane.

In an embodiment, the support part and the block may be detachably coupled to each other.

In an embodiment, a plurality of support coupling grooves may be defined in the support part along an extending direction of the support part, and the block may be detachably coupled to at least one of the plurality of support coupling grooves.

In an embodiment, the display panel may include a signal transmission region overlapping an electronic module disposed on the rear surface, and a non-transmission region adjacent to the signal transmission region, and the block may be disposed in a position corresponding to the signal transmission region.

In an embodiment, a thickness of the block may be equal to or greater than a thickness of the jig body.

In an embodiment, the block may have a width which is constant along a thickness direction.

In an embodiment of the invention, a display device manufacturing method may include providing a display panel on a stage in a way such that a rear surface of the display panel is exposed; adhering, to the rear surface of the display panel, a jig in which a jig opening corresponding to the display panel is defined; providing a coating liquid to an inside of the jig opening; curing the coating liquid to form a cover panel directly disposed on the rear surface; and removing the jig and the stage, wherein the jig includes a jig body in which the jig opening is defined by an inner side surface thereof, where the jib body has a size smaller than a size of the display panel, a support part coupled to the jig body, disposed above the jig opening, and crossing the jig opening, and a block coupled to the support part and disposed inside the jig opening.

In an embodiment, the jig further may comprise a coating layer disposed on the inner side surface of the jig body and an outer side surface of the block, and the coating layer may include fluorine.

In an embodiment, the coating liquid may comprise a base resin and a plurality of fillers dispersed in the base resin.

In an embodiment, a height of the coating liquid may be smaller than a height of the block.

In an embodiment, a hole corresponding to the block may be formed in the cover panel.

In an embodiment, the coating liquid may have a viscosity of about 10000 centipoise (cP) or less.

### BRIEF DESCRIPTION OF THE DRAWINGS

The above and other features of the invention will become more apparent by describing in further detail embodiments thereof with reference to the accompanying drawings, in which:

FIG. 1 is a perspective view of a display device manufacturing apparatus according to an embodiment of the invention;

FIG. 2A is a cross-sectional view taken along line I-I′ of FIG. 1 according to an embodiment of the invention;

FIG. 2B is a cross-sectional view taken along line II-II′ of FIG. 1 according to an embodiment of the invention;

FIG. 2C is a cross-sectional view taken along line III-III′ of FIG. 1 according to an embodiment of the invention;

FIG. 3 is a perspective view of a jig according to an embodiment of the invention;

FIG. 4 is a cross-sectional view taken along line IV-IV′ of FIG. 3 according to an embodiment of the invention;

FIG. 5 is a perspective view of a jig according to an embodiment of the invention;

FIG. 6 is a cross-sectional view taken along line V-V′ of FIG. 5 according to an embodiment of the invention;

FIGS. 7A to 7I are cross-sectional views and perspective views which illustrate some operations of a display device manufacturing method according to an embodiment of the invention;

FIG. 8 is a perspective view of a display device according to an embodiment of the invention;

FIG. 9 is an exploded perspective view of a display device according to an embodiment of the invention;

FIG. 10 is a cross-sectional view of a display panel according to an embodiment of the invention; and

FIG. 11 is a cross-sectional view of a display module according to an embodiment of the invention.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or region, layer, portion, or the like) is referred to as being “on”, “connected to” or “coupled to” another element, it may be directly disposed/connected/coupled to another element, or intervening elements may be disposed therebetween.

Like reference numerals or symbols refer to like elements throughout. In the drawings, the thickness, the ratio, and the dimension of the elements are exaggerated for effective description of the technical contents.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the invention. The singular forms include the plural forms, unless the context clearly indicates otherwise.

Also, the terms such as “below”, “lower”, “above”, “upper” and the like, may be used for describing a relationship of elements illustrated in the figures. It will be understood that the terms have a relative concept and are described on the basis of the orientation depicted in the figures.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

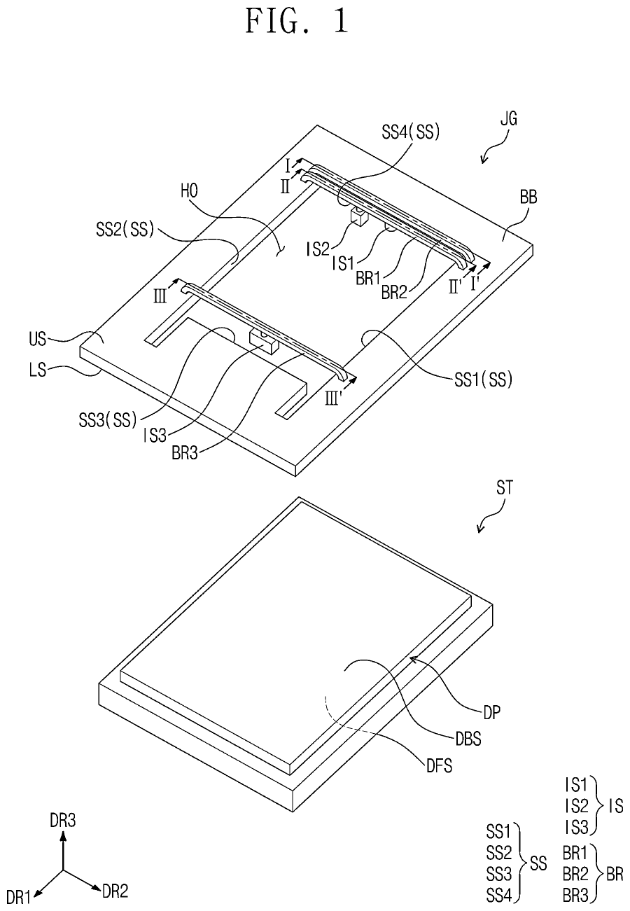

FIG. 1 is a perspective view of a display device manufacturing apparatus according to an embodiment of the invention.

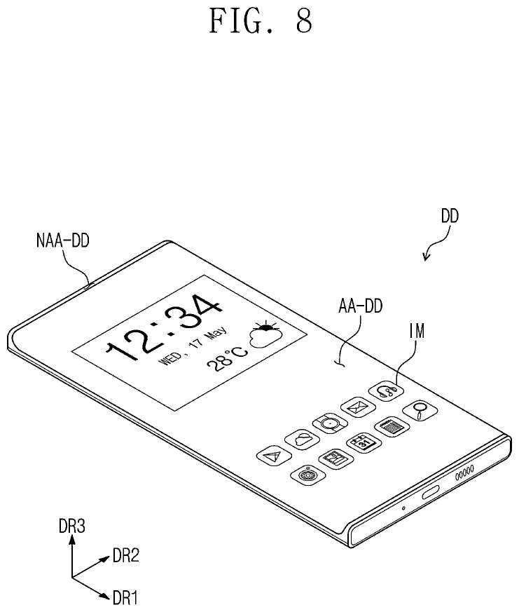

Referring to FIG. 1, an embodiment of the display device manufacturing apparatus, with which a display device DD (see FIG. 8) is manufactured, may include a jig JG and a stage ST. The display device manufacturing apparatus may further include other general-purpose components in addition to the jig JG and the stage ST.

The stage ST may be a flat board on which the display panel DP is provided. However, a shape of the stage ST is not limited thereto, and any component, on which the display panel DP may be stably placed, may be provided for the stage ST. In an embodiment, for example, a seating groove, in which the display panel DP is placed, may be defined in the stage ST. The stage ST may include a suction apparatus such that the display panel DP is fixed thereon.

The display panel DP may be provided on the stage ST in a way such that a rear surface DBS opposed to a front surface DFS of the display panel DP is exposed. That is, the front surface DFS, which is a light-emitting surface of the display panel DP, may be placed to face an upper surface of the stage ST.

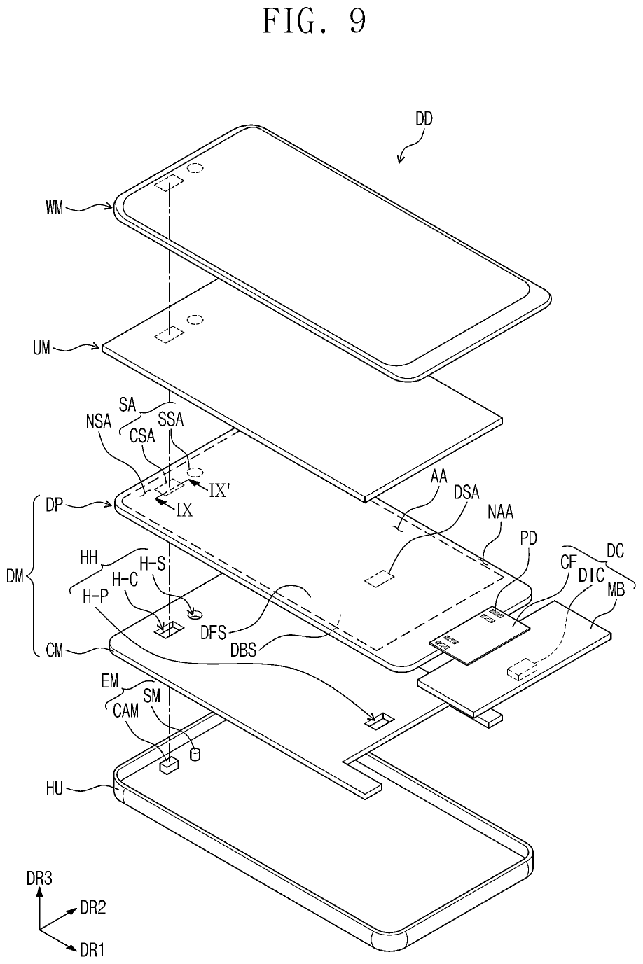

The jig JG may include a jig body BB, a support part BR, and a block IS. The jig JG may be provided on the rear surface DBS of the display panel DP, and a jig opening HO corresponding to the display panel DP may be defined in the jig JG. The jig JG includes the support part BR and the block IS, and thus it is possible to easily form a hole of a cover panel CM (see FIG. 9) which is applied onto the rear surface DBS of the display panel DP.

The jig body BB may include a lower surface LS, defined by a first direction DR1 and a second direction DR2 crossing the first direction DR1, and an upper surface US defined as a plane opposed to the lower surface LS in a third direction DR3. The lower surface LS and the upper surface US of the jig body BB may be parallel to each other. The third direction DR3 may be defined as a direction perpendicularly extending to a plane defined by the first and the second directions DR1 and DR2. Hereinafter, in this specification, the wording “when viewed on a plane” or “when viewed in a plan view” means a state when viewed in the third direction DR3.

In this specification, the first direction DR1 and the second direction DR2 may be orthogonal to each other, and the third direction DR3 may be a normal direction of a plane defined by the first direction DR1 and the second direction DR2. In this specification, the phrase “on a plane” may mean a case when viewed on a plane defined by the first direction DR1 and the second direction DR2, or when viewed in a plan view in a thickness direction, where the thickness direction may mean the third direction DR3 which is a normal direction of a plane defined by the first direction DR1 and the second direction DR2.

The jig opening HO may be defined by an inner surface SS of the jig body BB. The inner surface SS may connect the upper surface US and the lower surface LS of the jig JG. The inner surface SS may be disposed between the upper surface US and the lower surface LS.

The inner surface SS may include a first surface SS1 extending in the first direction DR1, a second surface SS2, which extends in the first direction DR1 and is opposed to the first surface SS1 in the second direction DR2, a third surface SS3 extending in the second direction DR2, and a fourth surface SS4 which extends in the first direction DR1 and is opposed to the third surface SS3. The first to fourth surfaces SS1 to SS4 may define the jig opening HO, or the jig opening HO may be surrounded by the first to fourth surfaces SS1 to SS4. The jig opening HO may have a size smaller than that of the display panel DP. The jig opening HO may have one of various shapes. FIG. 1 illustrates an embodiment where the jig opening HO has a shape in which a portion of a lower surface of a quadrilateral shape protrudes on a plane. However, this is illustrated as an example of a shape, and a shape of the jig opening HO may be variously modified.

In such an embodiment, the jig body BB is provided with an opened jig opening HO formed therein, and may thus be utilized as an open mask when a cover panel CM (see FIG. 9) is formed on the rear surface DBS of the display panel DP. Accordingly, it may be possible to change a thickness of a coating liquid being provided by using the open mask makes.

The support part BR may be coupled to the jig body BB, be disposed above the jig opening HO, and cross the jig opening HO. The support part BR may cross the jig opening HO along the second direction DR2 in which a width of the jig opening HO is small or relatively short. In this case, a length of the support part BR is shortened, and thus bending deformation due to gravity may be substantially reduced and effectively prevented.

The support part BR may be provided in plurality, and one block IS may be coupled to each of the plurality of support parts BR. The support part BR may include a first support part BR1, a second support part BR2, and a third support part BR3. On a plane, the support part BR1 may cross, in the second direction DR2, the jig opening HO in an upper part of the jig opening HO. On a plane, the second support part BR2 may cross, in the second direction DR2, the jig opening HO in a lower part than the first support part BR1. On a plane, the third support part BR3 may cross, in the second direction DR2, the jig opening HO in a lower part of the jig opening HO. However, the number of the support parts BR is not limited thereto, and may be changed based on the number of holes provided for the cover panel CM (see FIG. 9).

The block IS may be coupled to the support part BR and disposed inside the jig opening HO. The block IS may form a hole of the cover panel CM (see FIG. 9). The block IS may be provided in plurality, and the provided blocks IS may each be coupled to support part BR.

The block IS may include a first block IS1, a second block IS2, and a third block IS3. The first block IS1 may be coupled to the first support part BR1 and disposed at a center of the first support part BR1. The first block IS1 has a cylindrical shape, and may be disposed in a position corresponding to a sensor sensing region SSA (see FIG. 9) to be described later. The second block IS2 may be coupled to the second support part BR2 and disposed to be biased toward one side from the center of the second support part BR2. The second block IS2 has a rectangular parallelepiped shape, and may be disposed in a position corresponding to a camera sensing region CSA (see FIG. 9) to be described later. The third block IS3 may be coupled to the third support part BR3 and disposed at a center of the third support part BR3. The third block IS3 has a rectangular parallelepiped shape, and may be disposed in a position corresponding to a bonding region DSA (see FIG. 9) to be described later.

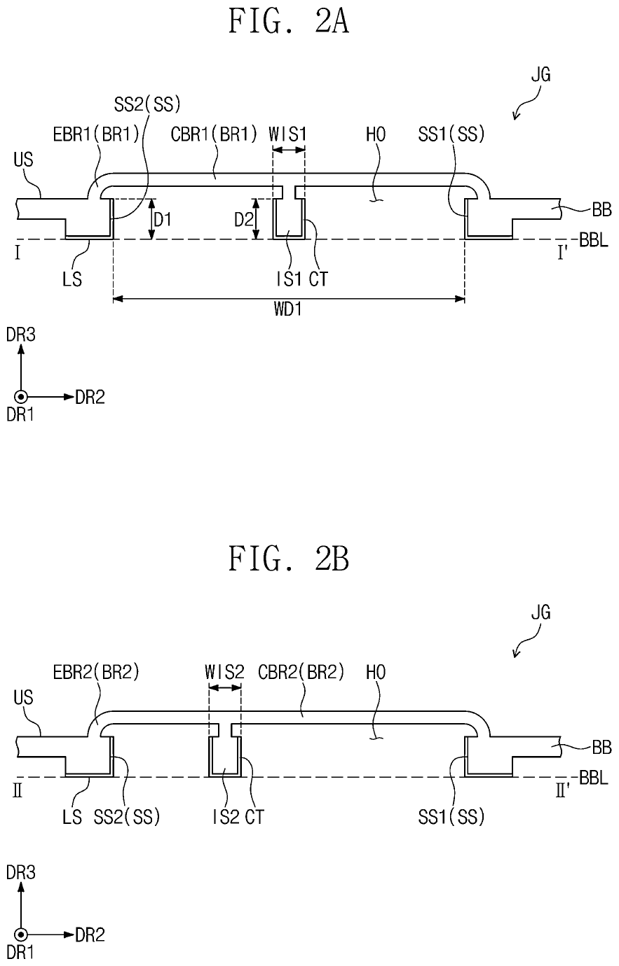

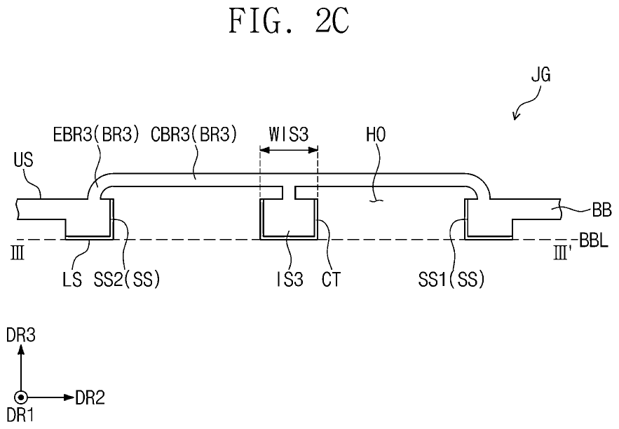

FIGS. 2A to 2C are cross-sectional views illustrating a structure of a jig JG according to an embodiment of the invention. Specifically, FIG. 2A is a cross-sectional view taken along line I-I′ of FIG. 1 according to an embodiment of the invention, FIG. 2B is a cross-sectional view taken along line II-II′ of FIG. 1 according to an embodiment of the invention, and FIG. 2C is a cross-sectional view taken along line III-III′ of FIG. 1 according to an embodiment of the invention.

Referring to FIG. 2A, an inner surface SS of the jig JG may define a jig opening HO. A first block IS1 may be disposed inside the jig opening HO, and a first support part BR1 may pass above the jig opening HO. The first width WD1 of the jig opening HO along the second direction DR2 may be smaller than the width of the display panel DP (see FIG. 1) along the second direction DR2.

The first support part BR1 may include a first support body CBR1 and first terminal portions EBR1. The first support body CBR1 may overlap the jig opening HO and cross the jig opening HO. The first support body CBR1 may have a bar shape extending in the second direction DR2. The first terminal portions EBR1 may extend from both ends of the first support body CBR1 and be coupled to a jig body BB. The first terminal portions EBR1 may be bent at one-side ends of the first support body CBR1 and coupled to an upper surface US of the jig body BB.

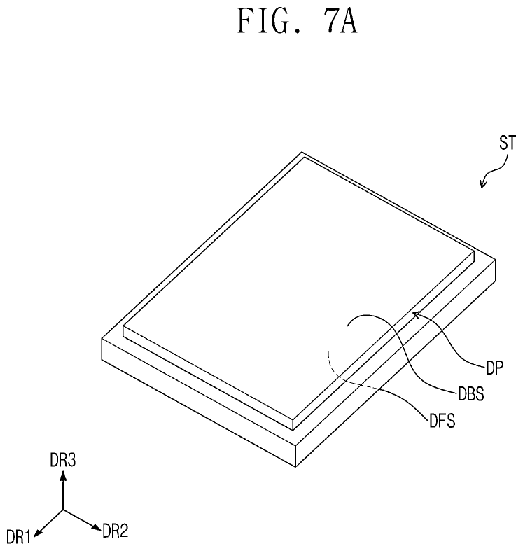

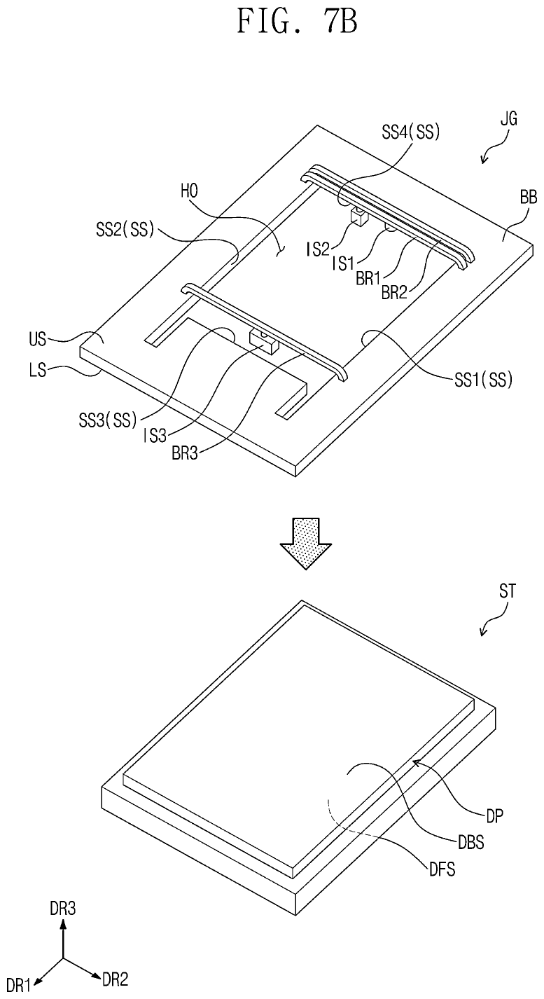

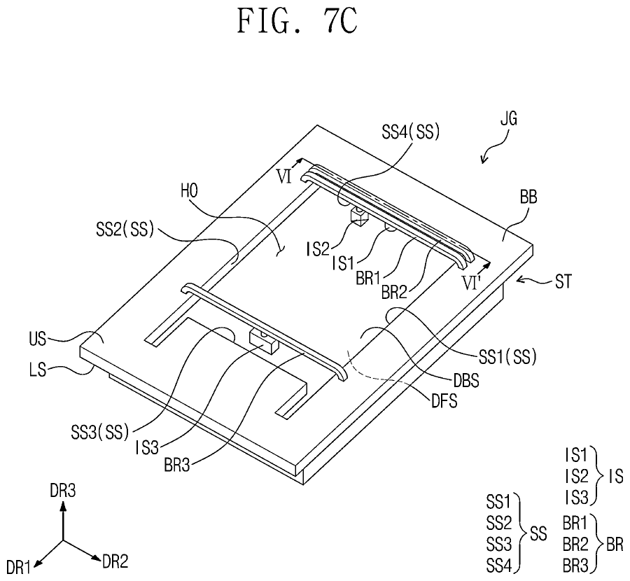

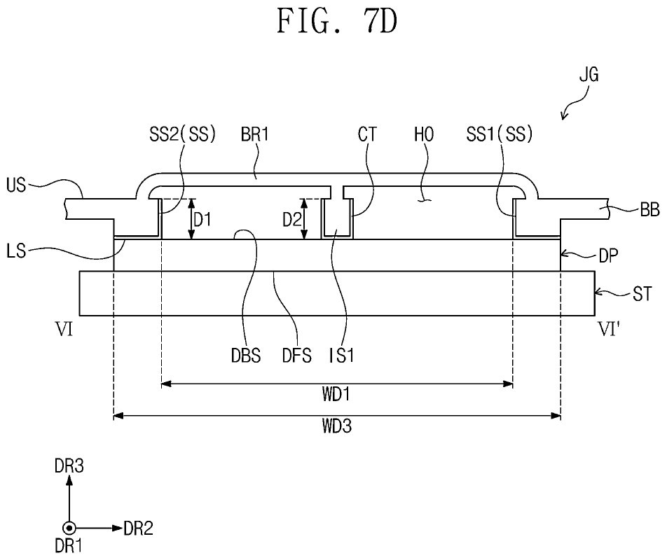

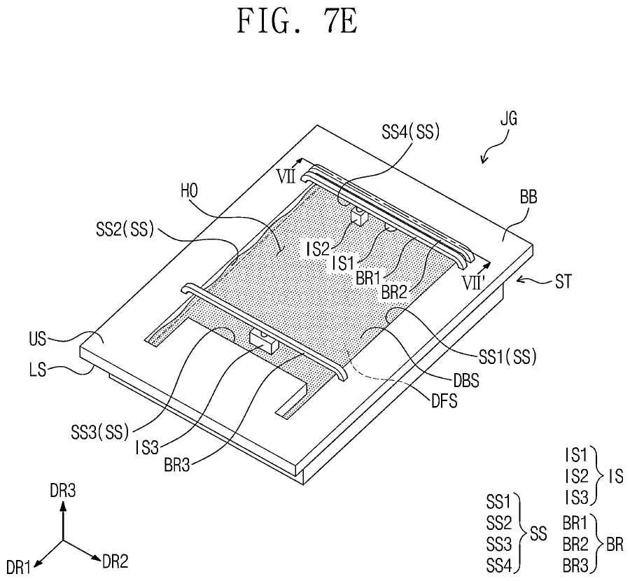

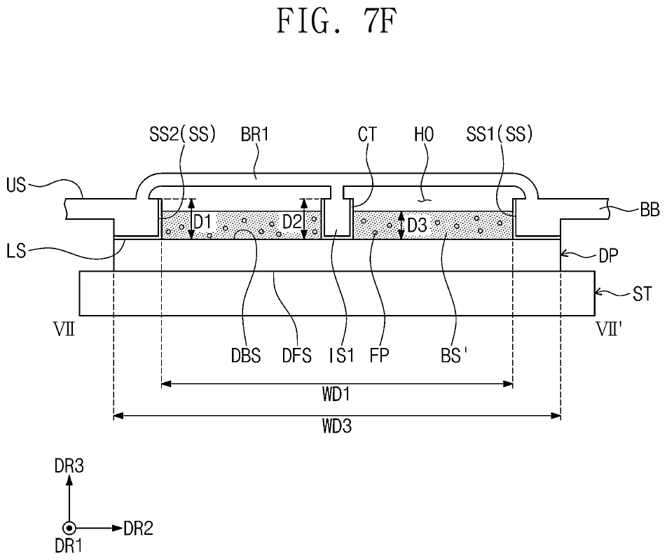

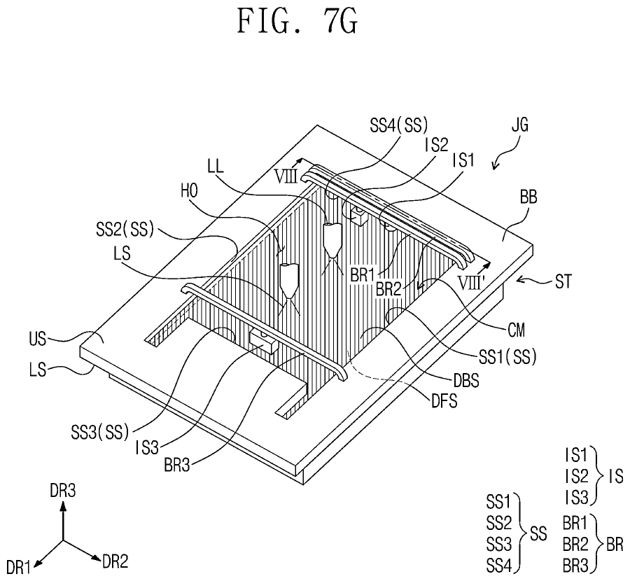

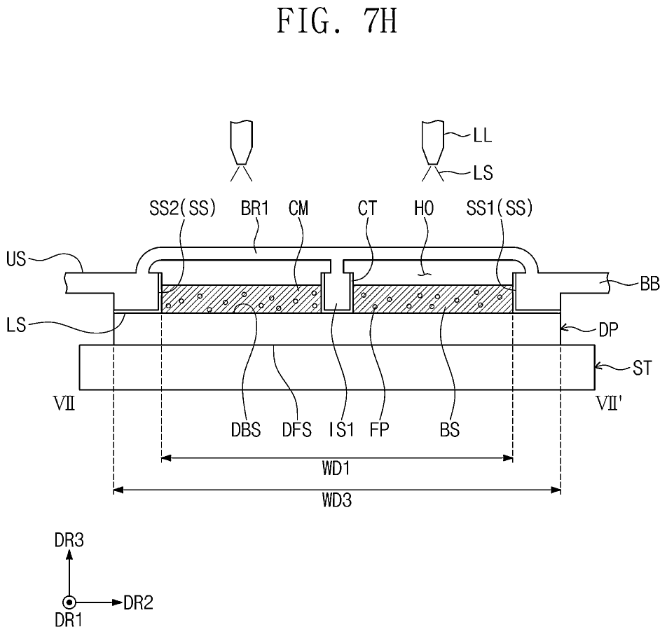

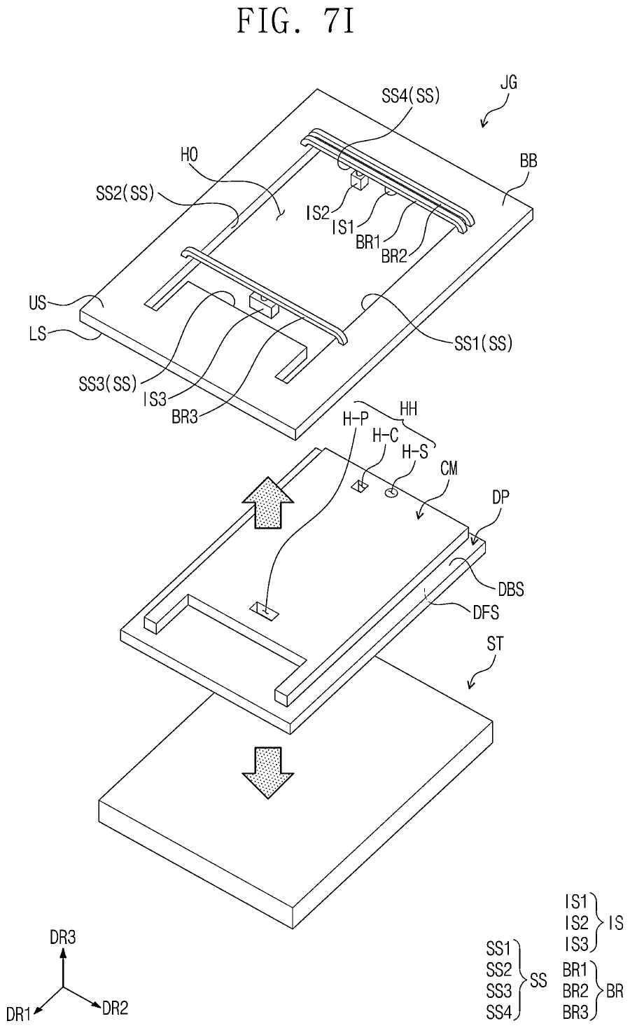

A lower surface LS of the jig body BB and a lower surface of the first block IS1 may be disposed on a same plane BBL. Accordingly, when making the jig JG adhere to a rear surface DBS (see FIG. 7D) of a display panel DP (see FIG. 7D), the jig JG may be adhered to the rear surface DBS without spacing.

A width WIS1 of the first block IS1 may be constant along the third direction DR3 which is the thickness direction. Accordingly, when a hole is formed in a cover panel CM (see FIG. 9) to be describe later, a hole having a constant width may be formed in the cover panel CM. The thickness D2 of the first block IS1 in the third direction DR3 is equal to or greater than the thickness D1 of the jig body BB in the third direction DR3. In a case where the thickness D2 of the first block IS1 is smaller than the thickness D1 of the jig body BB, the coating liquid may be present on an upper surface of the first block IS1 when a coating liquid is provided to the jig opening HO. Accordingly, a hole passing through the cover panel CM (see FIG. 9) may not be formed.

A coating layer CT may be disposed on an inner surface SS of the jig body BB and an outer surface of the first block IS1. The coating layer CT may be disposed on the inner surface SS and the lower surface LS of the jig body BB. The coating layer CT may be disposed on the outer surface and the lower surface of the first block IS1. The coating layer CT may contain fluorine. The coating layer CT may be a fluorine coating layer composed of fluorine. The coating layer CT contains fluorine, and thus the jig JG may be easily removed when removed from a display panel DP (see FIG. 7I).

Referring to FIG. 2B, a second block IS2 may be disposed inside the jig opening HO, and a second support part BR2 may pass above the jig opening HO.

The second support part BR2 may include a second support body CBR2 and second terminal portions EBR2. The description of configurations of the second support body CBR2 and the second terminal portions EBR2 may be same as or similar to the description of the first support body CBR1 and the first terminal portions EBR1 which are illustrated in FIG. 2A.

The lower surface LS of the jig body BB and a lower surface of the second block IS2 may be disposed on the same plane BBL. A width WIS2 of the second block IS2 may be constant along the third direction DR3 which is the thickness direction. The second block IS2 may be disposed to be biased to the left side from a center of the second support body CBR2. A coating layer CT may be disposed on the inner surface SS and the lower surface LS of the jig body BB, and an outer surface and a lower surface of the second block IS2.

Referring to FIG. 2C, a third block IS3 may be disposed inside the jig opening HO, and a third support part BR3 may pass above the jig opening HO.

The third support part BR3 may include a third support body CBR3 and third terminal portions EBR3. The configurations or features of the second support body CBR2 and the second terminal portions EBR2 may be the same as or similar to the those of the first support body CBR1 and the first terminal portions EBR1, which are described above with reference to FIG. 2A.

The lower surface LS of the jig body BB and a lower surface of the third block IS3 may be disposed on a same plane BBL. A width WIS3 of the third block IS3 may be constant along the third direction DR3 which is the thickness direction. The third block IS3 may be disposed at a center of the third support body CBR3. A coating layer CT may be disposed on the inner surface SS and the lower surface LS of the jig body BB, and an outer surface and a lower surface of the third block IS3.

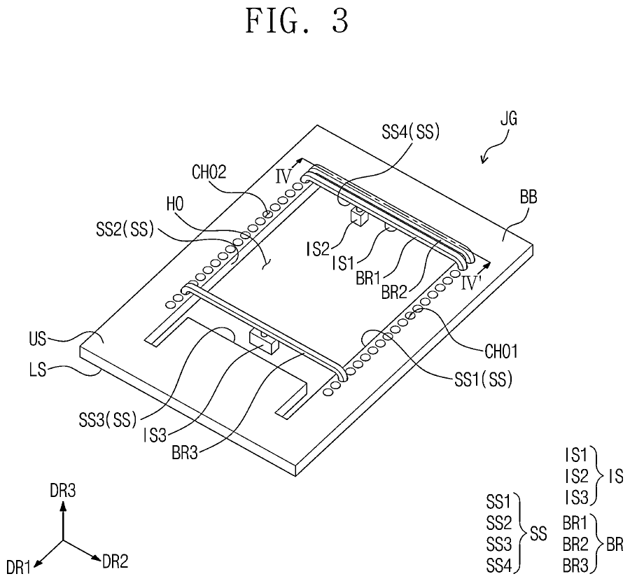

FIG. 3 is a perspective view of a jig according to an embodiment of the invention. Hereinafter, for convenience of description, any repetitive detailed descriptions of the same or like elements as those described above with reference to FIGS. 1 to 2C will be omitted.

Referring to FIG. 3, in an embodiment, coupling grooves CHO1 and CHO2 may be defined in an upper surface US of a jig body BB. Terminal portions of a support part BR may be detachably coupled to the coupling grooves CHO1 and CHO2. In such an embodiment, since the support part BR and the jig body BB are detachably coupled to each other, various shapes of cover panels CM (see FIG. 9) may be manufactured by utilizing the jig JG.

In an embodiment, the coupling grooves CHO1 and CHO2 may be provided in plurality and arranged on an upper surface US along the first direction DR1. Alternatively, the plurality of coupling grooves CHO1 and CHO2 may be arranged along the second direction DR2. In such an embodiment, the support part BR may extend along the first direction DR1.

The coupling grooves CHO1 and CHO2 may include a first coupling groove CHO1 and a second coupling groove CHO2. The first coupling groove CHO1 may be disposed in a portion, of the upper surface US, which is adjacent to a first surface SS1. The first coupling groove CHO1 may be provided in plurality. The plurality of first coupling grooves CHO1 may be arranged in the first direction DR1 along the first surface SS1.

The second coupling groove CHO2 may be disposed in a portion, of the upper surface US, which is adjacent to a second surface SS2. The second coupling groove CHO2 may be provided in plurality. The plurality of second coupling grooves CHO2 may be arranged along the second surface SS2 in the first direction DR1.

Terminal portions of each of first to third support parts BR1, BR2, and BR3 may be detachably coupled to corresponding first coupling groove CHO1 and the second coupling groove CHO2. A position of each of the first to third support parts BR1, BR2, and BR3 on a plane may be changed based on the positions of the coupling grooves CHO1 and CHO2 coupled thereto. Accordingly, positions, on a plane, at which blocks IS1, IS2, and IS3 are respectively coupled to the first to third support parts BR1, BR2, and BR3 may be changed.

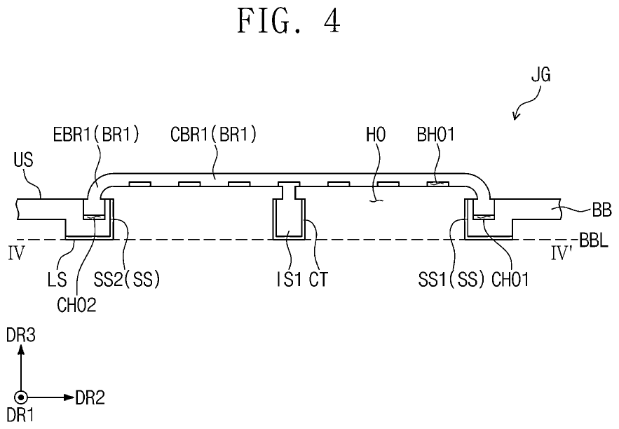

The support part BR may be detachably coupled to the block IS. A description thereof will be described later with reference to FIG. 4.

FIG. 4 is a cross-sectional view taken along line IV-IV′ of FIG. 3 according to an embodiment of the invention. In FIG. 4, the description will be made with reference to cross-sectional views of the first support part BR1 and the first support block IS, but it would be understood that the contents or features of the first support part BR1 and the first support block IS to be described may be similarly applied to the second and third support parts BR2 and BR3 and the second and third support blocks IS2 and IS3.

Referring to FIG. 4, in an embodiment, first terminal portions EBR1 of the first support part BR1 may be detachably coupled to a first coupling groove CHO1 and a second coupling groove CHO2. The first terminal portions EBR1 may be coupled to the first coupling groove CHO1 and the second coupling groove CHO2 corresponding thereto. A position, of the first coupling groove CHO1 coupled to one first terminal portion EBR1 along the first direction DR1 on a plane, may be the same as a position of the second coupling groove CHO2 along the first direction DR1 on a plane. In this case, any detachably coupling method may be used as a method of coupling the first terminal portions EBR1 to the first and second coupling grooves CHO1 and CHO2. In an embodiment, for example, the first terminal portions EBR1 may be detachably coupled to the first and second coupling grooves CHO1 and CHO2 through a screw fastening manner.

The first support part BR1 and the first support block IS may be detachably coupled to each other. A support part coupling groove BHO1 may be defined in a lower surface of a first support body CBR1 of the first support part BR1. The support part coupling groove BHO1 may be provided in plurality, and the plurality of support part coupling grooves BHO1 may be arranged along the second direction DR2 which is an extending direction of the first support part BR1. The first block IS1 may be detachably coupled to at least one support part coupling groove BHO1. Any detachably coupling method may be used as a method of coupling the first block IS1 to the support part coupling groove BHO1. In an embodiment, for example, the first block IS1 and the support part coupling groove BHO1 may be detachably coupled to each other through a screw fastening manner.

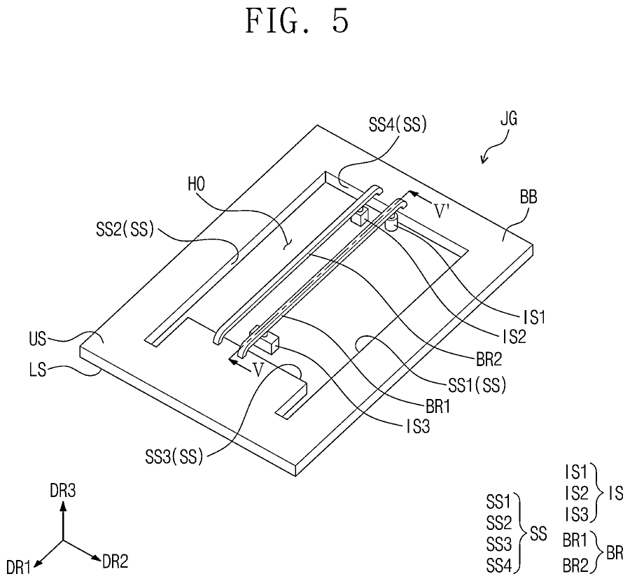

FIG. 5 is a perspective view of a jig according to an embodiment of the invention.

Referring to FIG. 5, in an embodiment, a support part BR may cross a jig opening HO along a direction in which a width of the jig opening HO is great or relatively long. The support part BR may cross the jig opening HO along the first direction DR1. The support part BR may include a material having a durability and rigidity high enough to be able to prevent bending deformation caused by gravity.

The support part BR may be provided in plurality, and at least one block IS may be coupled to each of the plurality of support parts BR. The support part BR may include a first support part BR1 and a second support part BR2. The first support part BR1 may be disposed, on a plane, at a center of the jig opening HO, and extend in the first direction DR1. The second support part BR2 may be disposed, on a plane, to be biased to the left side from the center of the jig opening HO, and extend in the first direction DR1. The plurality of blocks IS1 and IS3 may be coupled to the first support part BR1 and a second block IS2 may be coupled to the second support part BR2.

Both of the first block IS1 and the third block IS3 may be disposed, on a plane, at the center of the jig opening HO. The first block IS1 may be disposed, on a plane, in an upper part of the jig opening HO, and the third block IS3 may be disposed, on a plane, in a lower part of the jig opening HO. Both of the first and third blocks IS1 and IS3 may be coupled to the first support part BR1.

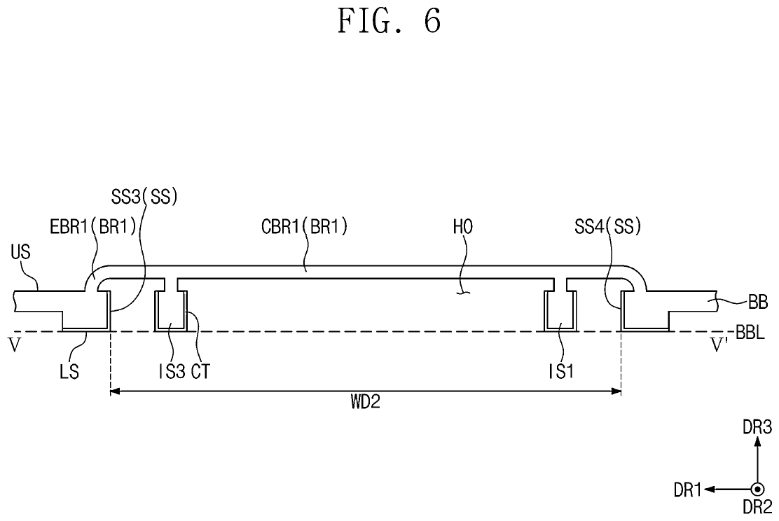

FIG. 6 is a cross-sectional view taken along line V-V′ of FIG. 5 according to an embodiment of the invention.

Referring to FIG. 6, in an embodiment, a first block IS1 may be coupled to one side of a first support body CBR1, and a third block IS3 may be coupled to the other side of the first support body CBR1. The width WD2 of a jig opening HO along the first direction DR1 may be smaller than the width of the display panel DP (see FIG. 1) along the first direction DR1. In this manner, the plurality of blocks IS1 and IS3 are coupled to one first support part BR1, and thus it is possible to reduce the number of the support parts BR (see FIG. 5) used for the jig JG.

FIGS. 7A to 7I are cross-sectional views and perspective views which illustrate some operations of a display device manufacturing method according to an embodiment of the invention.

Referring to FIG. 7A, in an embodiment of a display device manufacturing method (i.e., a method of manufacturing a display device), a display panel DP may be provided on a stage ST in a way such that a rear surface DBS of the display panel DP is exposed. A front surface DFS of the display panel DP may face an upper surface of the stage ST.

Referring to FIGS. 7B and 7C, a jig JG, in which a jig opening HO corresponding to the display panel DP is defined, may be adhered onto the rear surface DBS. Since the size of the jig opening HO is smaller than the size of the rear surface DBS, only a portion of the rear surface DBS may be exposed to the outside.

FIG. 7D may be a cross-sectional view taken along line VI-VI′ of FIG. 7C. Referring to FIG. 7D, the jig JG may be adhered onto the rear surface DBS of the display panel DP. A lower surface LS of a jig body BB and a lower surface of a first block IS1, which are coated with a coating layer CT, may be in contact with the rear surface DBS. The width WD1 of the jig opening HO along the second direction DR2 may be smaller than the width WD3 of the display panel DP along the second direction DR2. An upper part of the jig opening HO may be opened, and a side part and a lower part thereof may be respectively surrounded by the jig body BB and the rear surface DBS. The thickness D2 of the first block IS1 along the third direction DR3 is equal to or greater than the thickness D1 of the jig body BB along the third direction DR3.

Referring to FIG. 7E, a coating liquid COA may be provided to the inside of the jig opening HO in a state in which the jig JG is adhered onto the rear surface DBS. The coating liquid COA may be provided to only the inside of the jig opening HO. The provided coating liquid COA may fill a portion of the jig opening HO. The coating liquid COA may have a viscosity of about 10000 centipoise (cP) or less. If the coating liquid COA has a viscosity greater than about 10000 centipoise (cP), the coating liquid COA may not be evenly applied to the inside of the jig opening HO.

FIG. 7F may be a cross-sectional view taken along line VII-VII′ of FIG. 7E. In FIG. 7F, the first support part BR1 and the first block IS1 are shown, but the features described herein with reference to FIG. 7F may also be similarly applied to the second and third support parts BR2 and BR3 and the second and third blocks IS2 and IS3. Referring to FIG. 7F, a coating liquid COA may be provided to the inside of the jig opening HO. The height D3 of the provided coating liquid COA may be smaller than the thickness D1 of the jig body BB along the third direction DR3, and the thickness D2 of the first block IS1 along the third direction DR3.

If the thickness D2 of the first block ISI is smaller than the thickness D1 of the jig body BB, there is possibility that the coating liquid is also present on an upper surface of the first block IS1 according to the amount of the coating liquid COA. Accordingly, in an embodiment, the thickness D2 of the first block IS1 is set to be equal to or greater than the thickness D1 of the jig body BB such that it possible to effectively prevent the coating liquid COA from remaining on an upper surface of the first block IS1. Since the coating liquid COA is absent in a portion occupied by the first block IS1, the portion may become a hole in a cover panel CM (see FIG. 9) to be described later.

A lower surface of the first block IS1 and a lower surface LS of the jig body BB may be present on a same plane. Accordingly, the rear surface DBS of the display panel DP and the lower surface of the first block IS1 may be adhered to each other without any spacing therebetween, and the rear surface DBS of the display panel DP and the lower surface LS of the jig body BB may be adhered to each other without spacing. Therefore, it is possible to effectively prevent the coating liquid COA from flowing between the rear surface DBS and the lower surface LS of the jig body BB. Furthermore, it is possible to effectively prevent a hole of the cover panel CM (see FIG. 9) not from being formed due to the coating liquid COA remaining on the lower surface of the first block IS1.

The coating liquid COA may include a base resin BS′ and a plurality of fillers FP dispersed in the base resin BS′. The base resin BS′ may include at least one selected from an acylate-based polymer, a urethane-based polymer, a silicone-based polymer, and an imide-based polymer. The base resin BS′ may be provided in a liquid state. The base resin BS′ may include a curable resin. In an embodiment, for example, the base resin BS′ may include a photocurable resin.

The plurality of fillers FP may be fillers dispersed in the base resin BS′. The plurality of fillers FP may each include an organic material or an inorganic material. In an embodiment, for example, the plurality of fillers FP may each include graphite or metal particles. The plurality of fillers FP may include the same material or different materials. The plurality of fillers FP may be fillers that perform a same function as each other or different functions from each other. Accordingly, the formed cover panel CM (see FIG. 7I) may perform multiple functions such as supporting, heat-dissipating, shielding the display device.

FIG. 7H may be a cross-sectional view taken along line VIII-VIII′ of FIG. 7G. Referring to FIGS. 7G and 7H, the coating liquid COA (see FIG. 7E) may be cured to form a cover panel CM directly disposed on the rear surface DBS of the display panel DP. In this specification, the phrase ‘directly disposed’ may mean that two components are disposed in contact with each other without an adhesive member or adhesive layer for adhesion therebetween. Light LS may be emitted by using a light irradiation apparatus LL disposed above an opened upper surface of the jig opening HO. The emitted light LS may be ultraviolet rays.

The base resin BS′ (see FIG. 7F) including photocurable materials may be cured by the emitted light to form the base layer BS. Accordingly, the cover panel CM including the base layer BS and the plurality of fillers FP may be formed.

FIGS. 7G and 7H illustrate an embodiment where a coating liquid COA (see FIG. 7E) is cured through photocuring, but not being limited thereto. Alternatively, the coating liquid COA (see FIG. 7E) may be thermally cured. In such an embodiment, since there is a possibility that the coating liquid COA (see FIG. 7E) volatilizes, the coating liquid COA (see FIG. 7E) may be applied to a thickness greater than a target thickness of a cover panel CM. Since an upper surface of the jig JG having the jig opening HO defined therein is opened, it is possible to change the thickness of the applied coating liquid COA (see FIG. 7E), and thus a curing method may be changed.

Referring to FIG. 7I, the jig JG and the stage ST may be removed from the display panel DP and the cover panel CM formed on the rear surface DBS. In an embodiment, as described above, the coating layer CT (see FIG. 7H) including fluorine is applied onto the jig body BB of the jig JG and the blocks IS1, IS2, and IS3, and thus the jig JG may be easily removed from the display panel DP.

FIG. 8 is a perspective view of a display device according to an embodiment of the invention, and FIG. 9 is an exploded perspective view of a display device according to an embodiment of the invention. FIGS. 8 and 9 are respectively a perspective view and an exploded perspective view of a display device DD manufactured through a series of processes of FIGS. 7A to 7I.

FIG. 8 illustrates an embodiment where the display device DD is a mobile phone as an example. However, the display device DD is not limited thereto, and may be a small-or medium-sized display device such as a tablet computer, a car navigation system, a game console, a wearable device, or a camera.

The display device DD may display an image IM through an active region AA-DD. The active region AA-DD may include a flat surface defined by the first direction DR1 and the second direction DR2. The active region AA-DD may further include a curved surface bent from at least one side of the flat surface defined by the first direction DR1 and the second direction DR2. In an embodiment, as shown in FIG. 8, the display device DD, includes two curved surfaces which are respectively bent from opposing sides of the flat surface defined by the first direction DR1 and the second direction DR2. However, a shape of the active region AA-DD is not limited thereto. In an embodiment, for example, the active region AA-DD may include only the flat surface, or further include at least two curved surfaces, for example, four curved surfaces respectively bent from four side surfaces.

The display device DD may include the active region AA-DD and a peripheral region NAA-DD adjacent to the active region AA-DD. The active region AA-DD may be a portion corresponding to the display region AA of the later-described display panel DP, and the peripheral region NAA-DD may be a portion corresponding to the non-display region NAA of the display panel DP.

The peripheral region NAA-DD is a region for blocking an optical signal, and may be a region which is disposed outside the active region AA-DD and surrounds the active region AA-DD. In an embodiment, the peripheral region NAA-DD may not be disposed on a front surface but a side surface of the display device DD. The peripheral region NAA-DD according to an embodiment may be omitted.

The display device DD according to an embodiment may include a window WM, a housing HU, a display module DM, a circuit board DC, and an upper member UM.

The display device DD according to an embodiment may include the window WM disposed on the display panel DP. The window WM provides an exterior surface of the display device DD. Although not illustrated, the window WM includes a base substrate, and may further include functional layers such as an anti-reflection layer, an anti-fingerprint layer, and a phase controlling optical layer.

In the display device DD according to an embodiment, the upper member UM may be disposed between the window WM and the display module DM, e.g., disposed below the window WM and above the display module DM. The upper member UM may include an anti-reflection layer and an input-detection sensor. The anti-reflection layer reduces an external light reflectance. The input-detection sensor detects an external input from a user. The upper member UM may further include an adhesive layer which bonds the anti-reflection layer and the input-detection sensor.

In the display device DD according to an embodiment, the display module DM may be disposed below the upper member UM. The display module DM may include a display panel DP and a cover panel CM.

The display panel DP may include a display region AA in which the image IM is displayed, and a non-display region NAA adjacent to the display region AA. That is, a front surface DFS of the display panel DP is a light-emitting surface, and may include the display region AA and the non-display region NAA. The display region AA may be activated in response to an electrical signal.

The non-display region NAA may be adjacent to the display region AA. The non-display region NAA may surround the display region AA. In the non-display region NAA, a driving circuit or a driving wire for driving the display region AA, various types of signal lines or pads for providing electrical signals to the display region AA, an electronic element, or the like, may be disposed.

The display region AA may include a signal transmission region SA and a non-transmission region NSA. The signal transmission region SA may overlap an electronic module EM, and the non-transmission region NSA may be disposed to surround at least a portion of the signal transmission region SA. The non-transmission region NSA may correspond to a region other than the signal transmission region SA in the display panel DP.

The signal transmission region SA may overlap the electronic module EM. The electronic module EM may receive an external input transmitted through the signal transmission region SA, or provide an output through the signal transmission region SA. The signal transmission region SA may include a camera sensing region CSA and a sensor sensing region SSA. Below the display panel DP, a camera module CAM may be disposed to overlap the camera sensing region CSA, and a sensor module SM may be disposed to overlap the sensor sensing region SSA. Although not illustrated, according to other embodiments, a predetermined opening may be defined in the signal transmission region SA of the display panel DP. Accordingly, a portion of the display panel DP may be penetrated.

FIG. 9 illustrates an embodiment where the signal transmission region SA includes the camera sensing region camera CSA and the sensor sensing region SSA as an example, but the number of the signal transmission region SA is not limited thereto. In the display panel DP, the single transmission region SA may be defined as a single region or three or more regions. FIG. 9 illustrates an embodiment where the signal transmission region SA each has a circular shape or a quadrilateral shape as an example. However, a shape of the signal transmission region SA is not limited thereto, and may be variously defined if necessary.

On a plane, the area of the signal transmission region SA may be smaller than the area of the non-transmission region NSA. The transmittance of the signal transmission region SA may differ from that of the non-transmission region NSA. The transmittance of the signal transmission region SA may be greater than the transmittance of the non-transmission region NSA.

In the display panel DP according to an embodiment, a portion of a driving circuit, a driving wire, or the like for driving pixels (not illustrated) arranged in the signal transmission region SA, may be arranged in a portion of the non-display region NAA or the non-transmission region NSA. Accordingly, the wiring density in the signal transmission region SA may be smaller than the wiring density of the non-transmission region NSA. However, an embodiment of the invention is not limited thereto, and the wiring density in the signal transmission region SA may be substantially the same as the wiring density in the non-transmission region NSA.

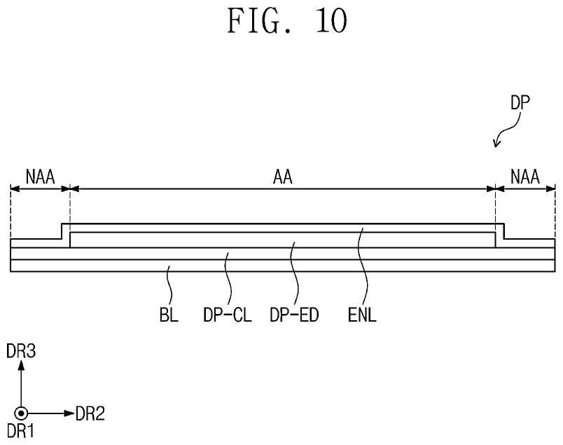

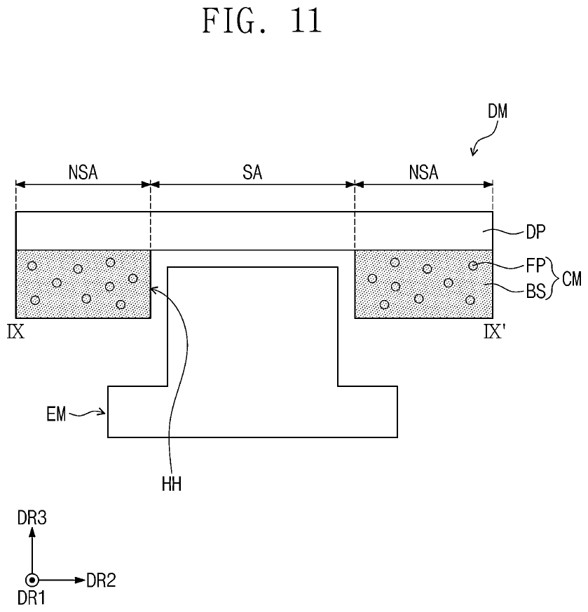

The display panel DP may include a light-emitting element layer DP-ED (see FIG. 10) including an organic light-emitting element, a quantum dot light-emitting element, a micro light emitting diode (LED) light-emitting element, or a nano LED light-emitting element, or the like. The light-emitting element layer DP-ED (see FIG. 10) may be configured to substantially generate images.

The cover panel CM may be disposed directly on a rear surface DBS of the display panel DP. The cover panel CM may be a member which supports the display panel DP and performs a heat dissipation function of emitting heat generated in the display panel DP. A hole HH may be defined in the cover panel CM. The hole HH may be defined in a region corresponding to the electronic module EM. The hole HH may be defined in a region corresponding to the bonding portion DIC, and the details thereof will be described later.

The hole HH may be defined in the cover panel CM overlapping the signal transmission region SA. According to an embodiment, the hole HH of the cover panel CM may be defined as a single hole or a plurality of holes. The hole HH may include a sensor hole H-S and a camera hole H-C. The sensor hole H-S may correspond to the above-described sensor sensing region SSA, and the camera hole H-C may correspond to the above-described camera sensing region CSA. That is, below the cover panel CM, the sensor module SM may be disposed so as to overlap the sensor hole H-S, and the camera module CAM may be disposed so as to overlap the camera hole H-C. A bonding hole H-P may correspond to a position of the bonding portion DIC when the flexible board CF is bent.

The display device DD may include the circuit board DC connected to the display panel DP. The circuit board DC may include a flexible board CF and a main board MB. The flexible board CF may include an insulating film and conductive wires mounted on the insulating film. The conductive wires are connected to the pads PD to electrically connect the circuit board DC to the display panel DP.

The main board MB may include signal lines and electronic elements which are not illustrated in the drawings. The electronic elements may be connected to the signal lines to be electrically connected to the display panel DP. The electronic elements generate various types of electrical signals, for example, signals for generating the image IM or signals for detecting external inputs, or process the detected signals. In an embodiment, a main board MB may be provided in plurality to correspond to respective electrical signals to be generated and processed, and is not limited to any one embodiment.

The bonding portion DIC of the main board MB may be bonded to the rear surface DBS in a bonding region DSA of the rear surface DBS of the display panel DP. When the flexible board CF is bent, the main board MB may be disposed below the cover panel CM. The bonding portion DIC may pass through the bonding hole H-P defined in the cover panel CM and be bonded to the bonding region DSA of the rear surface DBS.

In the display device DD according to an embodiment, the electronic module EM may be an electronic component which outputs or receives an optical signal. In an embodiment, for example, the electronic module EM may include the camera module CAM and the sensor module SM. The camera module CAM may receive external light through the camera sensing region CSA and capture an external image. In an embodiment, the sensor module SM may be a sensor such as a proximity sensor or infrared light-emitting sensor which outputs or receives external light through the sensor sensing region SSA.

The display device DD according to an embodiment may include a housing HU disposed below the cover panel CM. The display panel DP, etc., may be accommodated inside the housing HU. In the display device DD according to an embodiment, the window WM and the housing HU may be coupled to constitute an exterior of the display device DD.

FIG. 10 is a cross-sectional view of a display panel according to an embodiment of the invention.

Referring to FIG. 10, the display panel DP according to an embodiment may include a base substrate BL, a circuit layer DP-CL disposed on the base substrate BL, a light-emitting element layer DP-ED, and an encapsulation layer ENL. The base substrate BL may include a plastic substrate, a glass substrate, a metal substrate, an organic/inorganic composite material substrate, or the like. In an embodiment, for example, the base substrate BL may include at least one polyimide layer.

The circuit layer DP-CL may include at least one insulating layer, semiconductor patterns, and conductive patterns. The insulating layer includes at least one inorganic layer and at least one organic layer. The semiconductor patterns and the conductive patterns may form signal lines, a pixel driving circuit, and a scan driving circuit. Also, the circuit layer DP-CL may include a rear surface metal layer.

The light-emitting element layer DP-ED includes a display element, for example, a light-emitting element. In an embodiment, for example, the light-emitting element may be an organic light-emitting element, a quantum dot light-emitting element, a micro-LED light-emitting element, or a nano-LED light-emitting element. The light-emitting element layer DP-ED may further include an organic layer such as a pixel-defining film.

The light-emitting element layer DP-ED may be disposed in the display region AA. The non-display region NAA is disposed in the outer periphery of the display region AA and surrounds the display region AA. A light-emitting element may not be arranged in the non-display region NAA.

The encapsulation layer ENL may be disposed on the light-emitting element layer DP-ED and cover the light-emitting element layer DP-ED. The encapsulation layer ENL may be disposed on the display circuit layer DP-CL to seal the light-emitting element layer DP-ED. The encapsulation layer ENL may be a thin-film encapsulation layer including a plurality of organic thin films and an inorganic thin film. The encapsulation layer ENL may include a thin-film encapsulation layer having a stacked structure of an inorganic layer/organic layer/inorganic layer. A stacked structure of the encapsulation layer ENL is not particularly limited.

FIG. 11 is a cross-sectional view of a display module according to an embodiment of the invention. FIG. 11 may be a cross-sectional view taken along line IX-IX′ of FIG. 9.

Referring to FIG. 11, a display panel DP according to an embodiment of the invention may include a signal transmission region SA and a non-transmission region NSA. A cover panel CM according to an embodiment of the invention may overlap the non-transmission region NSA and not overlap the signal transmission region SA. Accordingly, the transmittance of the signal transmission region SA may be greater than the transmittance of the non-transmission region NSA.

The cover panel CM may be directly disposed on a rear surface DBS of the display panel DP. A hole HH may be defined in the signal transmission region SA in which the cover panel CM is not disposed. The hole HH may overlap an electronic module EM. At least a portion of the electronic module EM may be disposed to be inserted into the hole HH. In an embodiment, for example, the electronic module EM may be a camera module including a lens adjacent to the display panel DP. According to an embodiment, the lens of the camera module may be disposed to be inserted into the hole HH.

FIG. 11 illustrates a portion, of the display module DM, which corresponds to the sensing region SA described above. The display panel DP and the cover panel CM, which correspond to the bonding region DSA, have a same configuration as those of the display panel DP and the cover panel CM described above, and thus any repetitive detailed description thereof will be omitted.

A display device according to an embodiment of the invention may include a single coating layer which performs multiple functions in a lower part of a display panel, thereby reducing a thickness of the display device and the number of components. Including a light-emitting element in the display panel causes various side effects, and therefore, to mitigate such side effects, a typical display device includes a plurality of members such as a shielding layer, a heat dissipation layer, a cushion layer, and a support layer in a lower part of the display panel. In a display device according to an embodiment of the invention, a coating layer, including a plurality of fillers which perform the above-described functions, is disposed, and thus the display device not only performs functions performed by a plurality of conventional functional layers, but also achieves effects of reducing thickness and the number of components, and increasing manufacturing process efficiencies.

In a display device manufacturing apparatus according to embodiments of the invention, a cover panel with a hole defined therein may be manufactured by utilizing a jig which includes a support body, a support part, and a block.

In embodiments, the support body, the support part, and the block are detachably coupled to each other, and thus a position of the block may be changed according to a shape of the cover panel.

In a display device manufacturing method according to embodiments of the invention, a cover panel directly disposed on a rear surface of a display panel may be manufactured to have various shape by utilizing a jig which includes a support body, a support part, and a block.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device manufacturing apparatus comprising:
a stage, on which a display panel including a front surface, which is a light-emitting surface, and a rear surface opposed to the front surface is provided in a way such that the rear surface is exposed; and
a jig provided on the rear surface of the display panel on the stage, wherein a jig opening corresponding to the display panel is defined in the jig,
wherein the jig includes
a jig body in which the jig opening, is defined by an inner side surface thereof, wherein the jig body has a size smaller than a size of the display panel,
a support part coupled to the jig body, disposed above the jig opening, and crossing the jig opening, and
a block coupled to the support part and disposed inside the jig opening.

2. The display device manufacturing apparatus of claim 1, wherein the support part crosses the jig opening along a direction in which a width of the jig opening is relatively short.

3. The display device manufacturing apparatus of claim 1, wherein the support part comprises:
a support body overlapping the jig opening and crossing the jig opening; and
terminal portions extending from opposing ends of the support body, and coupled to the jig body.

4. The display device manufacturing apparatus of claim 3, wherein a coupling groove is defined in an upper surface of the jig body, and
the terminal portions of the support part are detachably coupled to the coupling grooves.

5. The display device manufacturing apparatus of claim 4, wherein the coupling groove is defined in plurality, and
the terminal portions of the support part are detachably coupled to two corresponding coupling grooves among a plurality of coupling grooves.

6. The display device manufacturing apparatus of claim 1, further comprising:
a coating layer disposed on the inner side surface of the jig body and on an outer side surface of the block.

7. The display device manufacturing apparatus of claim 1, wherein the support part is provided in plurality, the block is provided in plurality, and at least one of a plurality of blocks is coupled to each of a plurality of support parts.

8. The display device manufacturing apparatus of claim 1, wherein the support part crosses the jig opening along a direction in which a width of the jig opening is relatively long.

9. The display device manufacturing apparatus of claim 1, wherein a lower surface of the jig body and a lower surface of the block are disposed on a same plane.

10. The display device manufacturing apparatus of claim 1, wherein the support part and the block are detachably coupled to each other.

11. The display device manufacturing apparatus of claim 10, wherein a plurality of support coupling grooves are defined in the support part along an extending direction of the support part, and
the block is detachably coupled to at least one of the plurality of support coupling grooves.

12. The display device manufacturing apparatus of claim 1, wherein the display panel comprises a signal transmission region overlapping an electronic module disposed on the rear surface, and a non-transmission region adjacent to the signal transmission region, and
the block is disposed in a position corresponding to the signal transmission region.

13. The display device manufacturing apparatus of claim 1, wherein a thickness of the block is equal to or greater than a thickness of the jig body.

14. The display device manufacturing apparatus of claim 1, wherein the block has a width which is constant along a thickness direction.

15. A display device manufacturing method comprising:
providing a display panel on a stage in a way such that a rear surface of the display panel is exposed;
adhering, to the rear surface of the display panel, a jig in which a jig opening corresponding to the display panel is defined;
providing a coating liquid to an inside of the jig opening;
curing the coating liquid to form a cover panel directly disposed on the rear surface; and
removing the jig and the stage,
wherein the jig includes
a jig body in which the jig opening is defined by an inner side surface thereof, wherein the jib body has a size smaller than a size of the display panel,
a support part coupled to the jig body, disposed above the jig opening, and crossing the jig opening, and
a block coupled to the support part and disposed inside the jig opening.

16. The method of claim 15, wherein the jig further comprises a coating layer disposed on the inner side surface of the jig body and an outer side surface of the block, and
the coating layer includes fluorine.

17. The method of claim 15, wherein the coating liquid includes a base resin and a plurality of fillers dispersed in the base resin.

18. The method of claim 15, wherein a height of the coating liquid is smaller than a height of the block.

19. The method of claim 15, wherein a hole corresponding to the block is formed in the cover panel.

20. The method of claim 15, wherein the coating liquid has a viscosity of about 10000 centipoise (cP) or less.
